(19) United States
(12) Patent Application Publication
(10) Pub. No.: US 2018/0213642 A1
(43) Pub. Date: Jul. 26, 2018

(54) PRINTED CIRCUIT BOARD, MODULE USING PRINTED CIRCUIT BOARD, AND CAMERA MODULE USING PRINTED CIRCUIT BOARD

(71) Applicant: TAIYO YUDEN CO., LTD., Tokyo (JP)

(72) Inventors: Yuichi SUGIYAMA, Tokyo (JP); Masashi MIYAZAKI, Tokyo (JP); Hiroyuki KOBAYASHI, Tokyo (JP)

(73) Assignee: TAIYO YUDEN CO., LTD., Tokyo (JP)

(21) Appl. No.: 15/879,228

(22) Filed: Jan. 24, 2018

(30) Foreign Application Priority Data
Jan. 25, 2017 (JP) 2017-011612

(51) Int. Cl. H05K 1/09; H05K 1/03; H04N 5/225; H05K 3/44; H05K 1/02; H05K 3/40

(52) U.S. Cl. CPC H05K 1/09; H05K 1/0366; H04N 5/2253; H05K 2201/10151; H05K 1/0201; H05K 3/4038; H05K 2203/0323; H05K 3/44

(57) ABSTRACT

A printed circuit board includes a metal core substrate, an insulating layer formed on a surface of the metal core substrate, and a wiring pattern formed on the insulating layer. The metal core substrate includes a first metal layer made of a first metal material, and a second metal layer made of a second metal material differing from the first metal material, the second metal layer being laminated on the first metal layer. The elastic modulus of the second metal layer is lower than the elastic modulus of the first metal layer, and the thermal conductivity of the second metal layer is greater than the thermal conductivity of the first metal layer.

### BACKGROUND OF THE INVENTION

### Technical Field

The present invention relates to a printed circuit board and a module using a printed circuit board.

### Background Art

Printed circuit boards that have a metal core have been known, for example (e.g., Patent Document 1).

### Related Art Document

### Patent Document

Patent Document 1: Japanese Patent Application Laid-Open Publication No. 2012-212951

### SUMMARY OF THE INVENTION

A camera module installed in a highly functional portable terminal such as a smartphone is one of the thickest components of the portable terminal. In recent years, demand has been increasing for the camera module to be thinner, following an increase in demand for the portable terminal to be thinner and lighter.

In the camera module, there needs to be a certain amount of distance between the image sensor and the lens, and thus in order to make the camera module thinner, it is necessary to shorten the distance between the top of the image sensor and the bottom of the printed circuit board. One approach to this is to make the printed circuit board thinner.

However, making the printed circuit board thinner decreases the rigidity of the printed circuit board, and thus there is a risk that the mounting characteristics of the printed circuit board or strength as a camera module will be harmed. On the other hand, if the metal core substrate were to be formed of a metal material with a high elastic modulus in order to ensure rigidity of the printed circuit board, the thermal conductivity of such a metal material is often low, and thus heat generated inside the printed circuit board would accumulate.

Accordingly, the present invention is directed to a scheme that substantially obviates one or more of the problems due to limitations and disadvantages of the related art

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a printed circuit board in one aspect of the present invention includes: a printed circuit board, including: a metal core substrate; an insulating layer formed on a surface of the metal core substrate; and a wiring pattern formed on the insulating layer, wherein the metal core substrate includes a first metal layer made of a first metal material, and a second metal layer made of a second metal material differing from the first metal material, the second metal layer being laminated on the first metal layer, wherein an elastic modulus of the second metal layer is lower than an elastic modulus of the first metal layer, and wherein a thermal conductivity of the second metal layer is higher than a thermal conductivity of the first metal layer.

In another aspect, the present disclosure provides a printed circuit board, including: a metal core substrate; an insulating layer formed on a front surface and a rear surface of the metal core substrate; and a wiring pattern formed on the insulating layer, wherein the metal core substrate includes a first metal layer that includes, as a main material, a first metal material that is harder than copper, and a second metal layer made of a second metal material that mainly includes copper, the second metal layer being laminated on both surfaces of the first metal layer.

The problems and methods of solving the problems disclosed in the present application shall be made clear by the disclosures of the embodiments and drawings of the present invention.

According to the present disclosure, a printed circuit board that is thin yet strong and that has excellent heat dissipating characteristics can be obtained. It is to be understood that both the foregoing general description and the following detailed description are exemplary and explanatory, and are intended to provide further explanation of the invention as claimed.

### BRIEF DESCRIPTION OF THE DRAWINGS

FIG. 1 is a cross-sectional view schematically showing a printed circuit board of Embodiment 1.

FIG. 2 is a graph showing, for a metal core substrate of a uniform thickness, the relationship between the proportion of the thicknesses of the first and second metal layers constituting the metal core substrate and the deformation amount of the printed circuit board.

FIG. 3A is a cross-sectional view showing a step of preparing a first metal core in a manufacturing process of the printed circuit board of Embodiment 1.

FIG. 3B is a cross-sectional view showing a step of laminating a second metal core onto one surface of the first metal core in the manufacturing process of the printed circuit board of Embodiment 1.

FIG. 3C is a cross-sectional view showing a step of forming a first insulating layer on a surface of the second metal core in the manufacturing process of the printed circuit board of Embodiment 1.

FIG. 3D is a cross-sectional view showing a step of forming holes in the first insulating layer in the manufacturing process of the printed circuit board of Embodiment 1.

FIG. 3E is a cross-sectional view showing a step of forming a first wiring layer on a surface of the first insulating layer in the manufacturing process of the printed circuit board of Embodiment 1.

FIG. 3F is a cross-sectional view showing a step of forming holes in the first wiring layer in the manufacturing process of the printed circuit board of Embodiment 1.

FIG. 3G is a cross-sectional view showing a step of forming a second insulating layer on a surface of the first wiring layer in the manufacturing process of the printed circuit board of Embodiment 1.

FIG. 3H is a cross-sectional view showing a step of forming holes in the second insulating layer in the manufacturing process of the printed circuit board of Embodiment 1.

FIG. 3I is a cross-sectional view showing a step of forming a second wiring layer on a surface of the second insulating layer in the manufacturing process of the printed circuit board of Embodiment 1.

FIG. 3J is a cross-sectional view showing a step of forming holes in the second wiring layer in the manufacturing process of the printed circuit board of Embodiment 1.

FIG. 3K is a cross-sectional view showing a step of forming a solder resist layer on a surface of the second wiring layer in the manufacturing process of the printed circuit board of Embodiment 1.

FIG. 3L is a cross-sectional view showing a step of partially removing the solder resist layer in the manufacturing process of the printed circuit board of Embodiment 1.

FIG. 4 is a cross-sectional view schematically showing a printed circuit board of Embodiment 2.

FIG. 5A is a cross-sectional view showing a step of preparing a first metal core in a manufacturing process of the printed circuit board of Embodiment 2.

FIG. 5B is a cross-sectional view showing a step of laminating a second metal core onto one surface of the first metal core in the manufacturing process of the printed circuit board of Embodiment 2.

FIG. 5C is a cross-sectional view showing a step of forming holes in a substrate in the manufacturing process of the printed circuit board of Embodiment 2.

FIG. 5D is a cross-sectional view showing a step of forming a first insulating layer on both surfaces of the substrate in the manufacturing process of the printed circuit board of Embodiment 2.

FIG. 5E is a cross-sectional view showing a step of forming holes in the first insulating layer in the manufacturing process of the printed circuit board of Embodiment 2.

FIG. 5F is a cross-sectional view showing a step of forming a first wiring layer on a surface of the first insulating layer in the manufacturing process of the printed circuit board of Embodiment 2.

FIG. 5G is a cross-sectional view showing a step of forming holes in the first wiring layer in the manufacturing process of the printed circuit board of Embodiment 2.

FIG. 5H is a cross-sectional view showing a step of forming a second insulating layer on a surface of the first wiring layer in the manufacturing process of the printed circuit board of Embodiment 2.

FIG. 5I is a cross-sectional view showing a step of forming holes in the second insulating layer in the manufacturing process of the printed circuit board of Embodiment 2.

FIG. 5J is a cross-sectional view showing a step of forming a second wiring layer on a surface of the second insulating layer in the manufacturing process of the printed circuit board of Embodiment 2.

FIG. 5K is a cross-sectional view showing a step of forming holes in the second wiring layer in the manufacturing process of the printed circuit board of Embodiment 2.

FIG. 5L is a cross-sectional view showing a step of forming a solder resist layer on a surface of the second wiring layer in the manufacturing process of the printed circuit board of Embodiment 2.

FIG. 5M is a cross-sectional view showing a step of partially removing the solder resist layer in the manufacturing process of the printed circuit board of Embodiment 2.

FIG. 6 is a cross-sectional view schematically showing a printed circuit board of Embodiment 3.

FIG. 7A is a cross-sectional view showing a step of preparing a first metal core in a manufacturing process of the printed circuit board of Embodiment 3.

FIG. 7B is a cross-sectional view showing a step of laminating a second metal core onto both surfaces of the first metal core in the manufacturing process of the printed circuit board of Embodiment 3.

FIG. 7C is a cross-sectional view showing a step of forming holes in a substrate in the manufacturing process of the printed circuit board of Embodiment 3.

FIG. 7D is a cross-sectional view showing a step of forming a first insulating layer on both surfaces of the substrate in the manufacturing process of the printed circuit board of Embodiment 3.

FIG. 7E is a cross-sectional view showing a step of forming holes in the first insulating layer in the manufacturing process of the printed circuit board of Embodiment 3.

FIG. 7F is a cross-sectional view showing a step of forming a first wiring layer on a surface of the first insulating layer in the manufacturing process of the printed circuit board of Embodiment 3.

FIG. 7G is a cross-sectional view showing a step of forming holes in the first wiring layer in the manufacturing process of the printed circuit board of Embodiment 3.

FIG. 7H is a cross-sectional view showing a step of forming a second insulating layer on a surface of the first wiring layer in the manufacturing process of the printed circuit board of Embodiment 3.

FIG. 7I is a cross-sectional view showing a step of forming holes in the second insulating layer in the manufacturing process of the printed circuit board of Embodiment 3.

FIG. 7J is a cross-sectional view showing a step of forming a second wiring layer on a surface of the second insulating layer in the manufacturing process of the printed circuit board of Embodiment 3.

FIG. 7K is a cross-sectional view showing a step of forming holes in the second wiring layer in the manufacturing process of the printed circuit board of Embodiment 3.

FIG. 7L is a cross-sectional view showing a step of forming a solder resist layer on a surface of the second wiring layer in the manufacturing process of the printed circuit board of Embodiment 3.

FIG. 7M is a cross-sectional view showing a step of partially removing the solder resist layer in the manufacturing process of the printed circuit board of Embodiment 3.

FIG. 8 is a cross-sectional view schematically showing a printed circuit board of Embodiment 4.

FIG. 9A is a cross-sectional view showing a step of preparing a first metal core in a manufacturing process of the printed circuit board of Embodiment 4.

FIG. 9B is a cross-sectional view showing a step of forming holes in the first metal core in the manufacturing process of the printed circuit board of Embodiment 4.

FIG. 9C is a cross-sectional view showing a step of laminating a second metal core so as to surround a surface of the first metal core in the manufacturing process of the printed circuit board of Embodiment 4.

FIG. 9D is a cross-sectional view showing a step of forming a first insulating layer on a surface of the second metal core in the manufacturing process of the printed circuit board of Embodiment 4.

FIG. 9E is a cross-sectional view showing a step of forming holes in the first insulating layer in the manufacturing process of the printed circuit board of Embodiment 4.

FIG. 9F is a cross-sectional view showing a step of forming a first wiring layer on a surface of the first insulating layer in the manufacturing process of the printed circuit board of Embodiment 4.

FIG. 9G is a cross-sectional view showing a step of forming holes in the first wiring layer in the manufacturing process of the printed circuit board of Embodiment 4.

FIG. 9H is a cross-sectional view showing a step of forming a second insulating layer on a surface of the first wiring layer in the manufacturing process of the printed circuit board of Embodiment 4.

FIG. 9I is a cross-sectional view showing a step of forming holes in the second insulating layer in the manufacturing process of the printed circuit board of Embodiment 4.

FIG. 9J is a cross-sectional view showing a step of forming a second wiring layer on a surface of the second insulating layer in the manufacturing process of the printed circuit board of Embodiment 4.

FIG. 9K is a cross-sectional view showing a step of forming holes in the second wiring layer in the manufacturing process of the printed circuit board of Embodiment 4.

FIG. 9L is a cross-sectional view showing a step of forming a solder resist layer on a surface of the second wiring layer in the manufacturing process of the printed circuit board of Embodiment 4.

FIG. 9M is a cross-sectional view showing a step of partially removing the solder resist layer in the manufacturing process of the printed circuit board of Embodiment 4.

FIGS. 10A and 10B are views explaining the adhesiveness between a copper plating film and an insulating layer, wherein FIG. 10A shows the structure of a printed circuit board, and FIG. 10B schematically shows three types of structure of circled portion C1 in FIG. 10A.

FIGS. 11A to 11C are schematic views explaining the rigidity of the printed circuit board shown in FIG. 10A to which the reinforcing layer has been added, wherein FIG. 11A is a view showing a reinforcing layer, FIG. 11B is a cross-sectional view showing the structure of the printed circuit board, and FIG. 11C is a top view showing the structure of the printed circuit board layer.

FIG. 12 is a cross-sectional view schematically showing a printed circuit board having a third metal layer.

### DETAILED DESCRIPTION OF EMBODIMENTS

A printed circuit board according to the embodiments of the present disclosure will be described below with reference to the drawings where appropriate. In the descriptions below, the printed circuit board is described as being preferably used in a camera module. For example, in optical modules, it is required to have little deformation and excellent flatness because of the light. This is because the flatness makes it easy to adjust the reception of light, the optical path of emission light, and the like, and is thus convenient. In particular, flatness is demanded for portable bifocal camera modules, which have received attention recently, due to two imaging elements being arranged next to each other on the same board. Thus, there is demand for rigidity of the mounting board itself.

“Rigidity” means the degree of difficulty in changing (deforming) dimensions of an object against a bending or twisting force, and in this aspect, “high rigidity” means an excellent ability to keep a flat substrate flat.

However, the printed circuit board of the present invention is also applicable to technology other than camera modules. In the drawings, common or similar constituent elements are given the same or similar reference characters.

### Embodiment 1

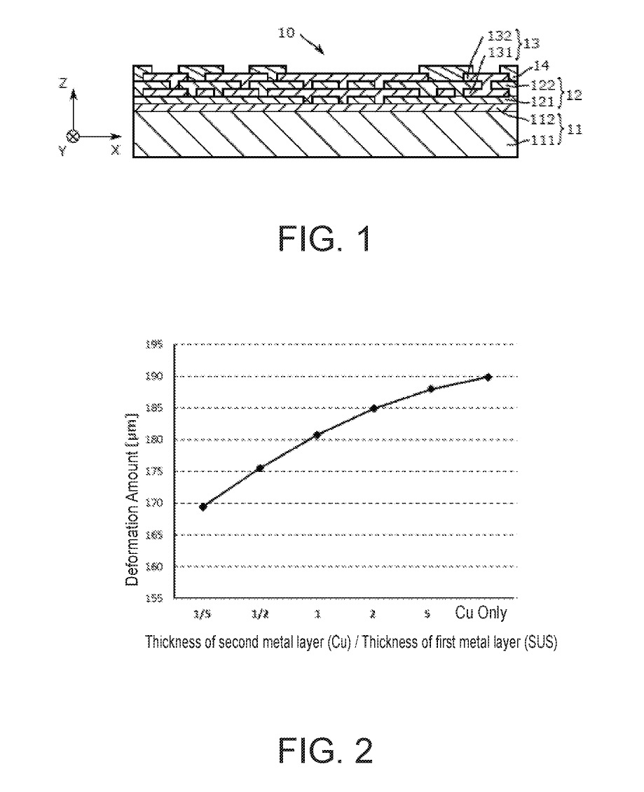

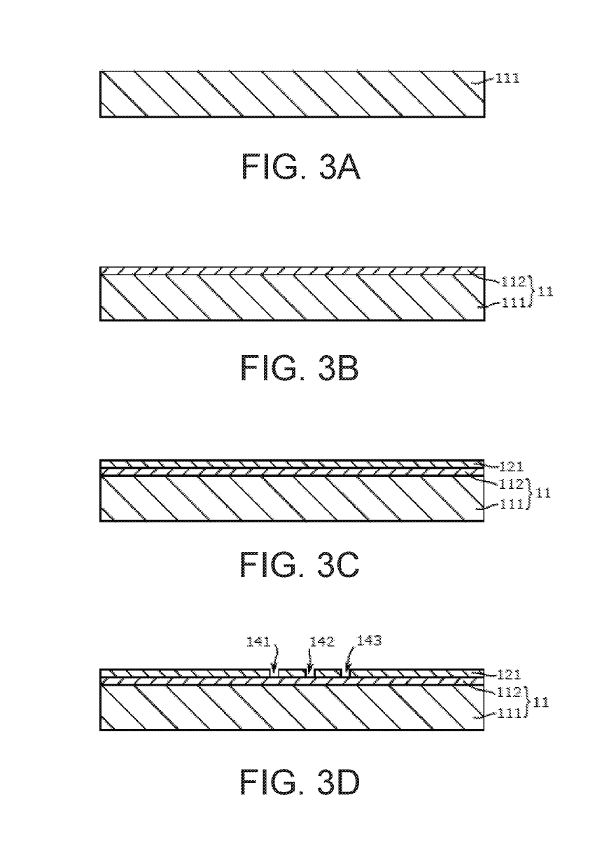

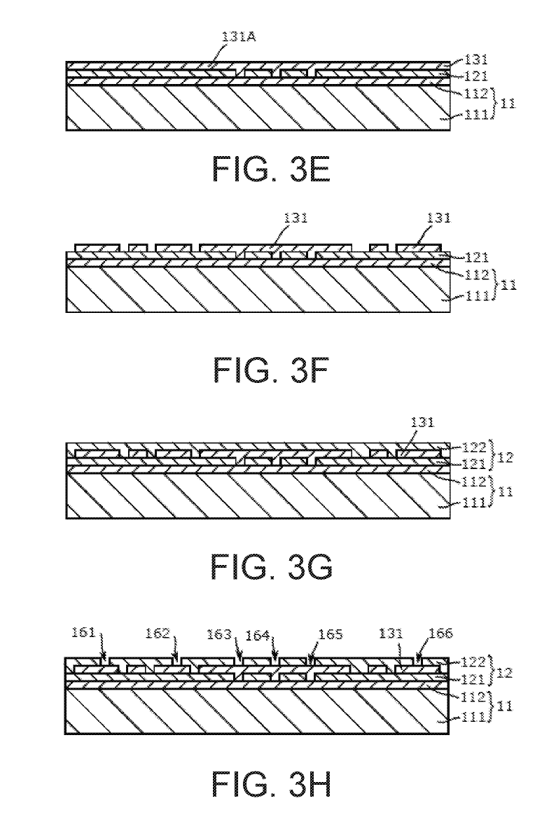

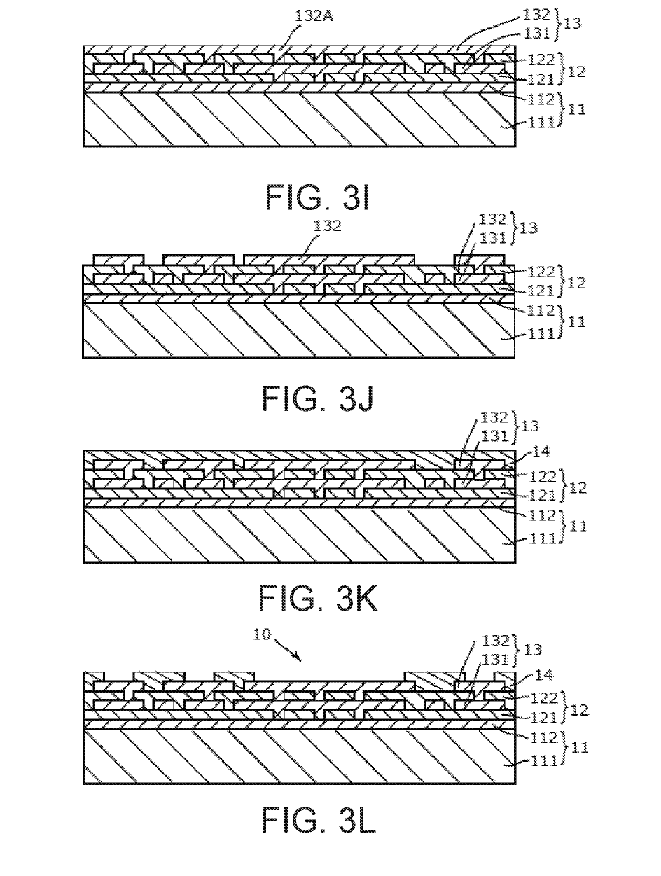

A printed circuit board 10 of Embodiment 1 will be described with reference to FIG. 1, FIG. 2, and FIGS. 3A to 3L. FIG. 1 is a cross-sectional view schematically showing a printed circuit board 10 of Embodiment 1. FIG. 2 is a graph showing, for a metal core substrate of a uniform thickness, the relationship between the proportion of the thicknesses of the first and second metal layers constituting the metal core substrate and the deformation amount of the printed circuit board. FIGS. 3A to 3L are cross-sectional views of one example of the manufacturing process of the printed circuit board 10 of Embodiment 1.

In FIGS. 1, 2, and 3A to 3L, the thickness direction of the printed circuit board 10 is the Z-axis direction, the direction extending from the front of the sheet of the figures shown to the back in a plane orthogonal to the Z-axis direction is the Y-axis direction, and the direction orthogonal to the Y-axis direction and Z-axis direction is the X-axis direction.

### <Configuration of Printed Circuit Board 10>

As shown in FIG. 1, the printed circuit board 10 includes at least a metal core substrate 11, insulating layer 12, wiring pattern 13, and solder resist layer 14.

The metal core substrate 11 is a plate-shaped member made of a plurality of metal materials (described later), and confers rigidity to the printed circuit board 10. In the present embodiment, the metal core substrate 11 also serves as a ground electrode (wiring). The thickness of the metal core substrate 11 is less than or equal to 250 μm, being 210 μm, 160 μm, or 120 μm, for example.

The metal core substrate 11 includes a first metal layer 111 containing a first metal material, and a second metal layer 112 which contains a second metal material differing from the first metal material and is laminated on the first metal layer 111. The second metal layer 112 is laminated on a surface on one side (in the present embodiment, the positive side of the Z-axis direction) of the first metal layer 111.

The first metal material is stainless steel, for example, and the second metal material is copper, for example. Covering the first metal layer with a metal having good electrical conductivity and thermal conductivity such as copper makes it possible to achieve strength, electrical conductivity, and thermal conductivity. The hardness of stainless steel is greater than the hardness of copper.

The stainless steel is generally alloy steel with iron (Fe) as a main component (at least 50%) and at least 10.5% of chromium (Cr). Stainless steel is also referred to as stainless or stain, and mainly categorized into five types depending on the metallographic structure: martensitic stainless steel, ferritic stainless steel, austenitic stainless steel, austenitic-ferritic duplex phase stainless steel, and precipitation hardening stainless steel. In terms of Vickers hardness (unit: HV), martensitic is 615, ferritic is 183, austenitic is 187, and precipitation hardening stainless steel is 375, which are all higher values than copper. There are other hard metals that could be used as the metal, but when considering the ease of availability, cost, and processing characteristics, stainless steel is one of the preferred materials. (The above explanation of the stainless steel is applicable to all embodiments.)

The thicknesses of the first metal layer 111 and the second metal layer 112 will be described in detail with reference to FIG. 2. FIG. 2 shows the relationship between the proportions of the thicknesses of the first metal layer (material: stainless steel) and second metal layer (material: copper) and the deformation amount of the printed circuit board for a rectangular printed circuit board having a 120 μm metal core substrate and dimensions of 17.8 mm×8.5 mm. The horizontal axis of the graph shown in FIG. 2 shows the proportion of the thickness of the second metal layer to the thickness of the first metal layer, and the vertical axis shows the deformation amount of the printed circuit board. As shown in FIG. 2, as the proportion of the first metal layer 111, which has a relatively high elastic modulus, increases (or, as the proportion of the second metal layer 112, which has a relatively low elastic modulus, decreases), there is less deformation of the printed circuit board 10, or in other words, the rigidity of the printed circuit board 10 increases.

Therefore, in the present embodiment, it is preferable that the thickness of the second metal layer 112 be less than the thickness of the first metal layer 111. When the thickness of the metal core substrate 11 is 120 μm, for example, it is preferable that the thickness of the first metal layer 111 be greater than 60 μm and that the thickness of the second metal layer 112 be less than 60 μm. By adopting such a metal core substrate 11, it is possible to improve the strength and rigidity of the printed circuit board 10 more than a substrate of the same thickness made of only the second metal material.

The preferable combination of the first metal material and the second metal material is stainless steel and copper, as described above. However, combinations of other metal materials that satisfy certain conditions (described later) may be used, such as a combination of one of iron and nickel with aluminum, for example. It is desirable, however, that the first metal material and second metal material be metals not susceptible to being diffused.

Furthermore, the electrical conductivity of the second metal layer 112 is greater than the electrical conductivity of the first metal layer 111, and the thermal conductivity of the second metal layer 112 is greater than the thermal conductivity of the first metal layer 111. The combination of the first metal material and second metal material described above satisfies this relationship. It is reasonable that one of the electrical conductivity and thermal conductivity of the second metal layer 112 may be higher than the corresponding physical properties of the first metal layer 111.

The elastic modulus of the second metal layer 112 is preferably lower than the elastic modulus of the first metal layer 111. The combination of the first metal material and second metal material described above also satisfies this relationship.

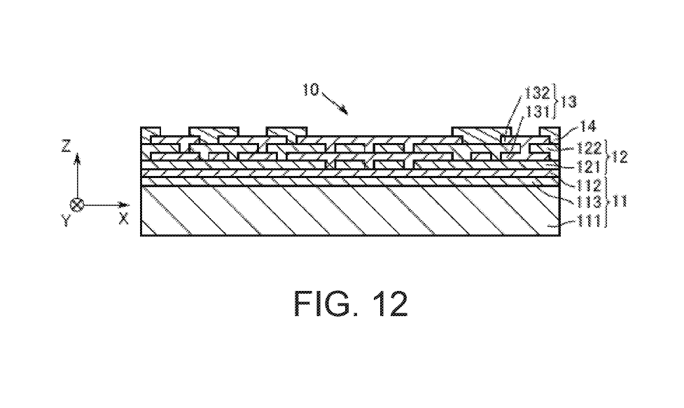

As shown in FIG. 12, the metal core substrate 11 may also have a third metal layer 113 as an intermediary metal between the first metal layer 111 and second metal layer 112. This enhances the adhesiveness between the first metal layer 111 and second metal layer 112. The third metal material contained in the third metal layer 113 is at least one selected from nickel, palladium, titanium, tungsten, chromium, cobalt, and tin, for example. The third metal material may also be diffused into the first metal material and second metal material, such as tin, for example.

In the present embodiment, the third metal material is a thin film less than 1 μm and has almost no effect on the mechanical properties of the metal core substrate 11. The third metal material may also be selected from two or more types of the metal materials described above.

The insulating layer 12 is formed on the surface of the metal core substrate 11. The insulating layer 12 is made of an epoxy resin, polyimide or bismaleimide triazine resin, or the like, for example, and glass fibers are provided in the resin. Instead of glass fibers, the resin may contain a filler such as aluminum oxide or silicon dioxide. Moreover, the resin may contain both glass fibers and a filler. The resin is generally a thermosetting synthetic resin.

In the present embodiment, the insulating layer 12 includes two layers: a first insulating layer 121 and a second insulating layer 122, but the number of layers of the insulating layer 12 may be modified as appropriate.

The wiring pattern 13 is formed on the insulating layer 12 and receives an insulation treatment. The material of the wiring pattern 13 is preferably the second metal material or a material having mechanical properties which is similar to those of the second metal material. When the second metal layer 112 contains copper, for example, the most suitable material for the wiring pattern 13 is copper.

It could rather be said that the main material of the second metal layer 112 is copper, and the wiring pattern is the same as this material or has copper as a main material.

In the present embodiment, the wiring pattern 13 includes two layers: a first wiring layer 131 and a second wiring layer 132, but the number of wiring layers included in the wiring pattern 13 may be modified as appropriate.

As will be clear from the manufacturing method described later, when the wiring layer is made of Cu, the second metal layer made of Cu or having Cu as the main material thereof is formed on the entire surface of the first metal layer 111. In the wiring layer, the GND wiring of any layer is mechanically and electrically connected to the second metal layer by a through-hole or via and is so-called grounded (grounded to a ground plane). If not grounded, the second metal layer 112 and first wiring layer have a capacitance formed via the insulating layer, and a GND with a particularly wide line width is also one of the reasons that the capacitance becomes greater.

The solder resist layer 14 is an insulating film that protects the circuit patterns formed on the printed circuit board 10 and is formed on the surface of the insulating layer 12. The solder resist layer 14 is made of a thermosetting epoxy resin, for example.

In the present embodiment, the printed circuit board 10 does not contain a built-in component, but the printed circuit board 10 may contain a build-in component.

The second metal layer 112 may be provided on the rear surface of the first metal layer 111. At such time, the intermediary metal layer described above may be provided.

The second metal layer 112 is preferably a plating film. This is preferable because, in the case of Cu, Cu that has grown by plating has a polycrystalline structure grown in the Z-direction (thickness direction) and fine recesses and protrusions are formed by an etching process such as a CZ process, which enhances adhesion with the insulating layer 121. This aspect will be described later.

### <Manufacturing Process of Printed Circuit Board 10>

The steps for manufacturing the printed circuit board 10 having the configuration described above will be explained with reference to FIGS. 3A to 3L. Individual printed circuit boards are fabricated by cutting a large-sized substrate containing a plurality of printed circuit boards arrayed in a matrix (in the X-axis direction and Y-axis direction), but the below explanation focuses on a single printed circuit board 10.

First, as shown in FIG. 3A, a first metal layer 111 is prepared in order to form the metal core substrate 11. If the printed circuit board 10 contains a built-in component, then a hole is additionally formed in the first metal layer 111, the built-in component is inserted into the hole, and then the hole is sealed with a resin.

Next, as shown in FIG. 3B, a film forming technique such as plating, sputtering, foil vacuum crimping, or foil diffusion bonding, for example, is used to form a second metal layer 112 on a surface on one side (here, the positive side in the Z-axis direction) of the first metal layer 111. Before the second metal layer 112 is formed, sputtering or plating, for example, may be used to form a third metal layer 113 on a surface on one side (here, the positive side in the Z-axis direction) of the first metal layer 111, as shown in FIG. 12.

The second metal layer 112 may also be formed on the rear surface of the first metal layer 111, and in such a case, the third metal layer 113 may be similarly formed on the rear surface.

After the metal core substrate 11 is formed as described above, the insulating layer 12 and wiring pattern 13 are formed on a surface on one side of the metal core substrate 11.

Specifically, as shown in FIG. 3C, the first insulating layer 121 is formed on the front surface of the second metal layer 112. Next, as shown in FIG. 3D, an etching treatment or laser processing method, for example, is used to form holes 141 to 143 in the first insulating layer 121.

Then, as shown in FIG. 3E, a plating method is used to form a first metal covering layer 131A such that the holes 141 to 143 are filled and the surface of the first insulating layer 121 is covered. Hereinafter, the metal covering layer, which will serve as a conductive pattern, is ordinarily Cu.

Next, as shown in FIG. 3F, the first metal covering layer 131A formed on the entire surface is patterned by wet etching, for example, to form the first wiring layer 131. The first wiring layer 131 and other wiring layers described later form wiring and electrodes. Furthermore, in the first wiring layer, wires or electrodes that need to be grounded are electrically connected to the first metal layer 111 and second metal layer 112 via the holes 141 to 143.

Next, as shown in FIG. 3G, the second insulating layer 122 is formed so as to cover the surface of the first wiring layer 131. Then, as shown in FIG. 3H, an etching treatment or laser processing method, for example, is used to form holes 161 to 166 in the second insulating layer 122. Thereafter, as shown in FIG. 3I, a plating method is used to form a second metal covering layer 132A such that the holes 161 to 166 are filled and the layer is provided on the entire front surface of the second insulating layer 122. Next, as shown in FIG. 3J, the second metal covering layer 132A is patterned to form the second wiring layer 132.

Thereafter, the solder resist layer 14 is formed on the front surface of the substrate. Specifically, as shown in FIG. 3K, the solder resist layer 14 is formed so as to cover the surface of the insulating layer 122 and the second wiring layer 132, and as shown in FIG. 3L, an etching treatment (development treatment) is used to partially remove the solder resist layer 14 and expose the second wiring layer 132. The second wiring layer 132 exposed from the solder resist serves as the component mounting electrode (described later), wire bonding electrode, or the like.

Thereafter, a dicer, for example, is used to cut the completed large-sized printed substrate to divide the substrate into individual pieces. The individual printed substrates then have camera components such as imaging elements mounted thereon, for example, and in this example semiconductor chips or passive components are mounted thereon.

As described above, in Embodiment 1, it is possible to obtain a metal core substrate 11 that is enhanced in strength than a substrate of the same thickness in which the core substrate is made of only the second metal material (e.g., copper); thus, it is possible to obtain a printed circuit board 10 that is thin yet strong.

This is because the first metal layer 111 has the metal substrate which is harder than Cu, thus making it possible to obtain a board that is thin yet strong, rigid, and flat. In particular, stainless steel is preferable due to having higher rigidity than Cu and being available at a relatively low cost.

Furthermore, it is possible to obtain a metal core substrate 11 having higher electrical conductivity than a substrate in which the core substrate is made of only the first metal material (e.g., stainless steel), and therefore it is possible to obtain a printed circuit board 10 that generates less heat than a board in which a metal core substrate is made of only the first metal material. This suppresses power consumption when the printed circuit board 10 is used as camera module component.

Moreover, it is possible to obtain a metal core substrate 11 having a higher thermal conductivity than a substrate made of only the first metal material; thus, it is possible to obtain a printed circuit board 10 with heat dissipating characteristics that exceed a board in which a metal core substrate is made of only the first metal material.

These are because when Cu is used as the second metal layer, the thermal conductivity of Cu is high and thus heat is efficiently transmitted to the first metal material (stainless steel), and also because Cu as the second metal layer has low resistance, which makes it possible to suppress heat from being generated by conduction.

In addition, using the same material or a material with mechanical properties similar to those of the second metal material as the material for the wiring (vias) makes it possible to enhance the connection reliability of the vias connected to the metal core substrate 11 more than in a substrate made of only the first metal material, which also makes it possible to reduce contact resistance.

### Embodiment 2

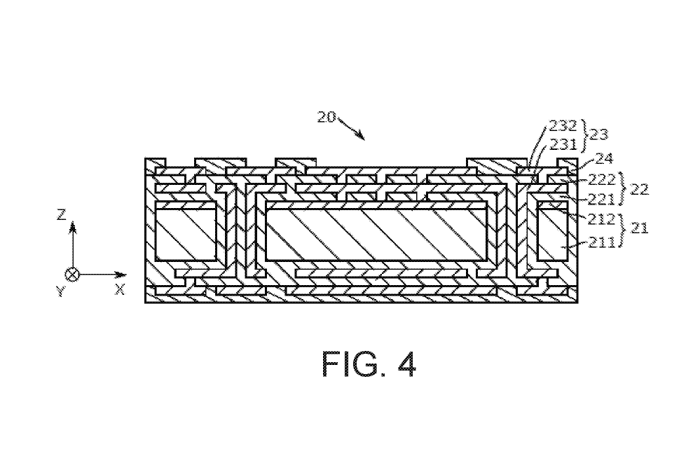

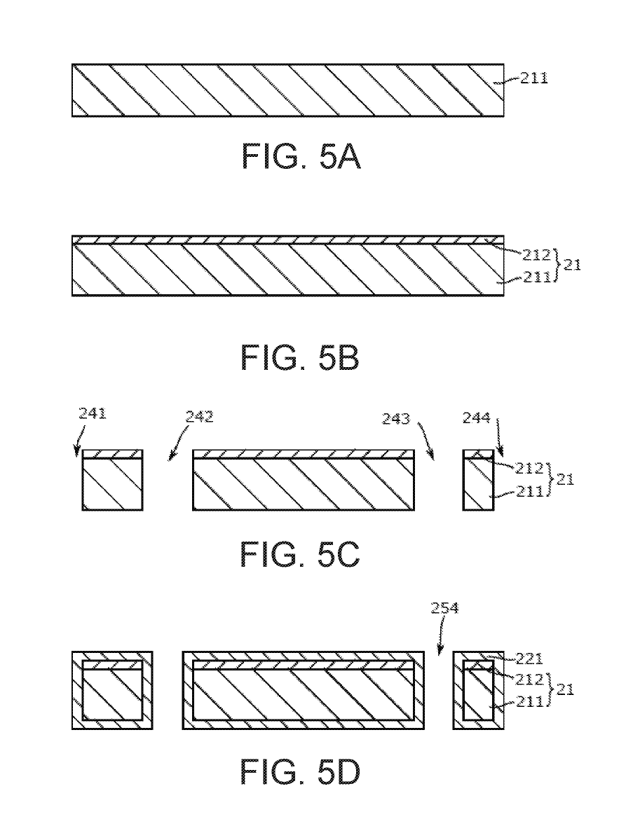

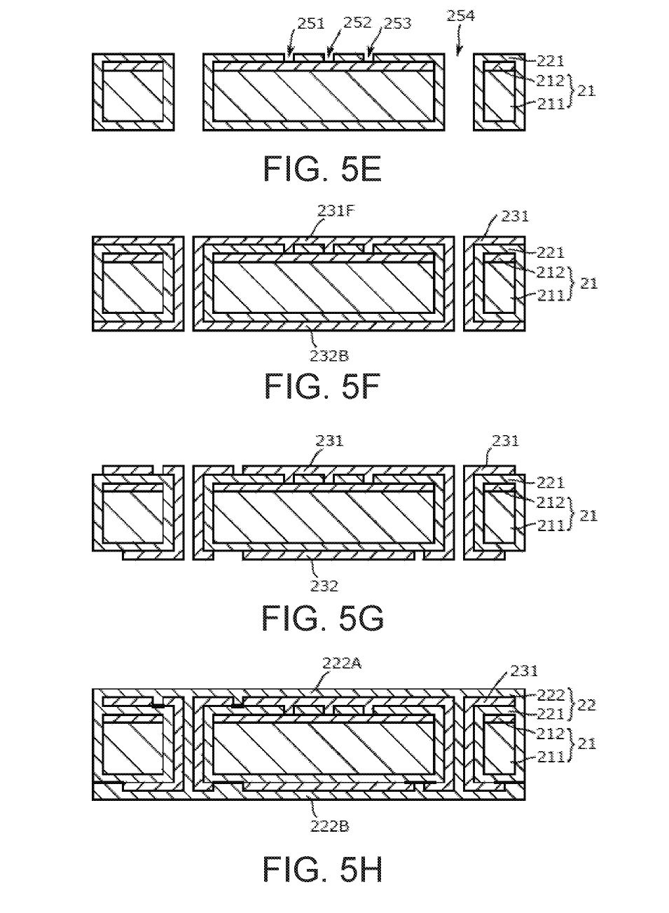

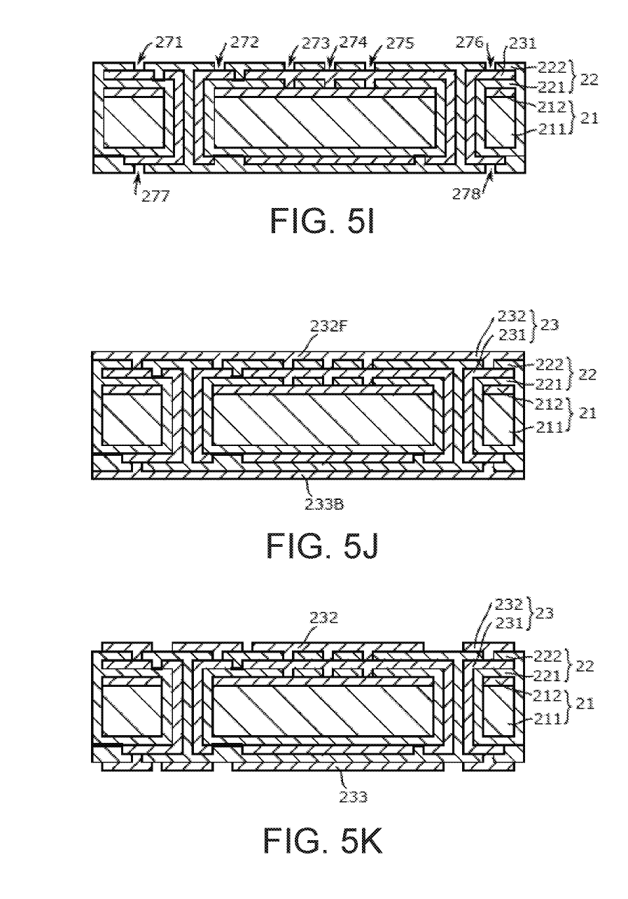

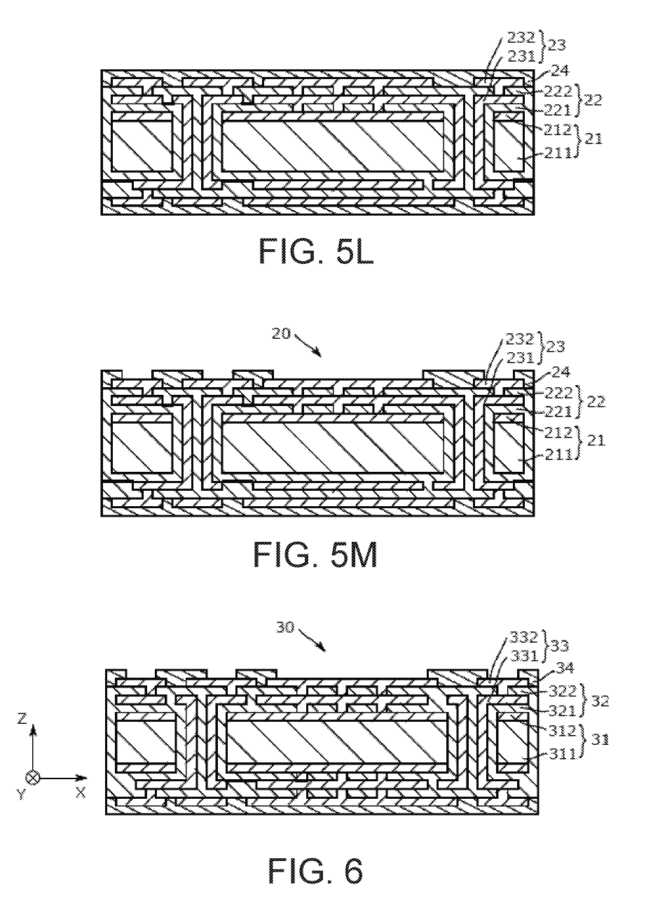

A printed circuit board 20 of Embodiment 2 will be described below with reference to FIGS. 4 and 5A to 5M. FIG. 4 is a cross-sectional view schematically showing a printed circuit board 20 of Embodiment 2. FIGS. 5A to 5M are cross-sectional views of one example of the manufacturing process of the printed circuit board 20 of Embodiment 2. In each drawing, the X-axis, Y-axis, and Z-axis are the same as in Embodiment 1.

### <Configuration of Printed Circuit Board 20>

As shown in FIG. 4, similar to the printed circuit board 10 of Embodiment 1, the printed circuit board 20 includes at least a metal core substrate 21, insulating layer 22, wiring pattern 23, and solder resist layer 24. However, the insulating layer 22, wiring pattern 23, and solder resist layer 24 are formed on both surfaces of the metal core substrate 21.

A second metal layer 212 (e.g., a Cu plating layer) is formed on one side (here, the positive side in the Z-axis direction) of a first metal layer 211 (e.g., stainless steel); thus, hardness is slightly increased as compared to the structure in FIG. 6 in which the layer is formed on both surfaces. Meanwhile, the GND wiring on the front of the core substrate is directly electrically connected to the second metal layer 212, but the GND wiring on the rear of the core substrate extends toward the front and is then grounded with the second metal layer. As will be described in the manufacturing method, both sides of the substrate have wiring, and thus through-holes are formed. Due to the core substrate being metal, an insulating material is filled into the holes, and after this the through-hole electrodes are formed.

The materials for forming the respective constituent elements of the printed circuit board 20 in Embodiment 2 are similar to Embodiment 1, and thus a detailed explanation thereof will be omitted.

### <Manufacturing Process of Printed Circuit Board 20>

The manufacturing process of the printed circuit board 20 will be described below with reference to FIGS. 5A to 5M. The general flow of the fabrication of the metal core substrate 21, the forming of the insulating layer 22 and wiring pattern 23, and the forming of the solder resist layer 24 is similar to Embodiment 1. However, as described above, in the printed circuit board 20 of Embodiment 2, the insulating layer 22, wiring pattern 23, and solder resist layer 24 are formed on both surfaces of the metal core substrate 21; thus, there are steps in Embodiment 2 that differ from the manufacturing process of Embodiment 1.

A more specific description will be provided below.

First, as shown in FIG. 5A, the first metal layer 211 is prepared in order to form the metal core substrate 21, and then as shown in FIG. 5B, the second metal layer 212 is formed and laminated by plating, for example, on a surface on one side (here, the positive side in the Z-axis direction) of the first metal layer 211. An intermediary layer may be interposed therebetween, similar to Embodiment 1. As shown in FIG. 5C, holes 241 to 244 are formed in the metal core substrate 21 by mechanical processing such as with a drill or by an etching treatment, for example.

Next, the process proceeds to a step of forming the insulating layer 22 and wiring pattern 23.

First, as shown in FIG. 5D, the holes 241 to 244 are filled, the first insulating layer 221 is formed so as to cover the surface of the metal core substrate 21, and thereafter a hole 254 to be used as a through-hole penetrating from front to rear is formed via laser processing or drill processing. Next, as shown in FIG. 5E, holes 251 to 253 are formed in the first insulating layer 221. Furthermore, the holes 251 to 253 are formed by etching or laser processing and are used as the substrate ground (GND) with the second metal layer 212.

Next, as shown in FIG. 5F, first metal covering layers 231F and 232B are formed to cover the front and rear while filling the holes 251 to 253. The hole 254 corresponding to the through-hole may have the covering layer formed on the sidewall thereof or may be completely filled by the covering layer.

Thereafter, as shown in FIG. 5G, the first metal covering layers 231F and 232B are patterned via etching, and the first wiring layers 231 and 232 are formed on the surface of the first insulating layer 221. The first wiring layers 231 and 232 are formed by patterning and serve as wiring, electrodes, or the like. In addition, during etching, if a plating film is formed on the side wall of the hole 254, the hole 254 is covered by a solder resist or the like so as to prevent etching of the side wall.

Thereafter, as shown in FIG. 5H, the second insulating layers 222A and 222B are formed on the front and rear of the substrate so as to cover the first wiring layers 231 and 232. In such a case, if the portion corresponding to the through-hole is open, the hole is filled with the second insulating layer.

Next, as shown in FIG. 5I, laser processing or etching is used to form holes 271 to 278 in the second insulating layers 222A and 222B. The holes 271 to 276 expose the first wiring layer 231, and the holes 277 to 278 expose the first wiring layer 232.

Thereafter, as shown in FIG. 5J, second metal covering layers 232F and 233B are formed so as to cover the front and rear of the substrate, fill the holes 271 to 278, and cover the surfaces of the second insulating layers 222A and 222B. A plating method is also used here. Next, as shown in FIG. 5K, the second metal covering layers 232F and 233B are patterned by etching to form the second wiring layers 232 and 233. The second wiring layer 232 serves as an electrode for electronic component mounting, wiring, or the like, and the second wiring layer 233 serves as an electrode for external connection or wiring.

Finally, as shown in FIG. 5L, the solder resist layer 24 is formed on the surfaces of the second wiring layers 232 and 233, and as shown in FIG. 5M, the solder resist layer 24 is partially removed to expose the second wiring layers 232 and 233. In FIG. 5M, the solder resist on the rear surface is not patterned, but if an external connection electrode is required, for example, the portion for the external connection electrode would be exposed from the solder resist.

Thereafter, the large-sized printed circuit board is divided into individual pieces, and camera components are attached to the individual printed boards, which is similar to Embodiment 1.

As described above, in Embodiment 2, it is possible to obtain a metal core substrate that is stronger than a substrate made of only the second metal material, in a manner similar to Embodiment 1. Furthermore, it is possible to obtain a metal core substrate with a higher electrical conductivity than a substrate made of only the first metal material. Furthermore, it is possible to obtain a metal core substrate with a higher thermal conductivity than a substrate made of only the first metal material.

Moreover, in Embodiment 2, the wiring pattern 23 is formed on both surfaces of the metal core substrate 21, and thus it is possible to make the printed circuit board 20 even smaller and more power efficient.

### Embodiment 3

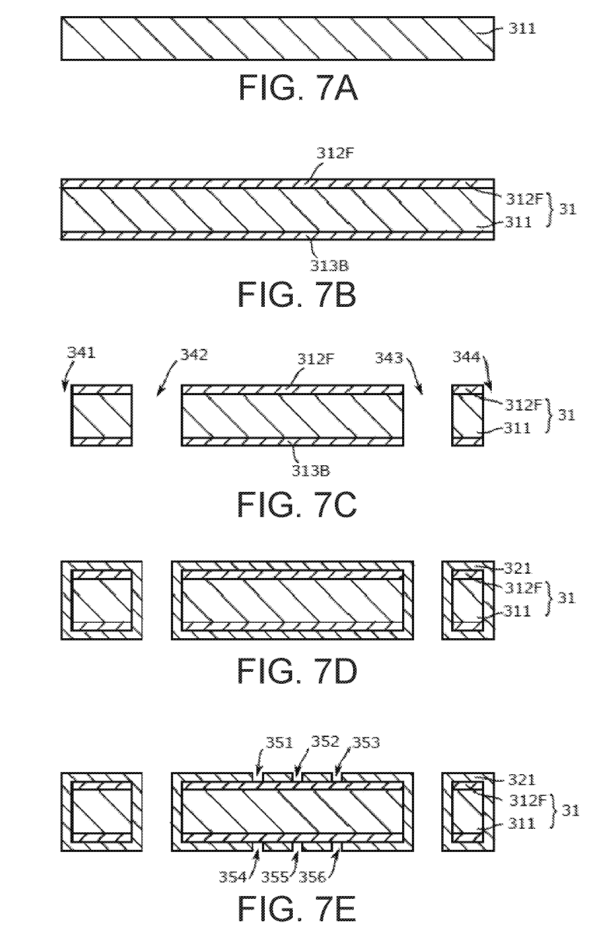

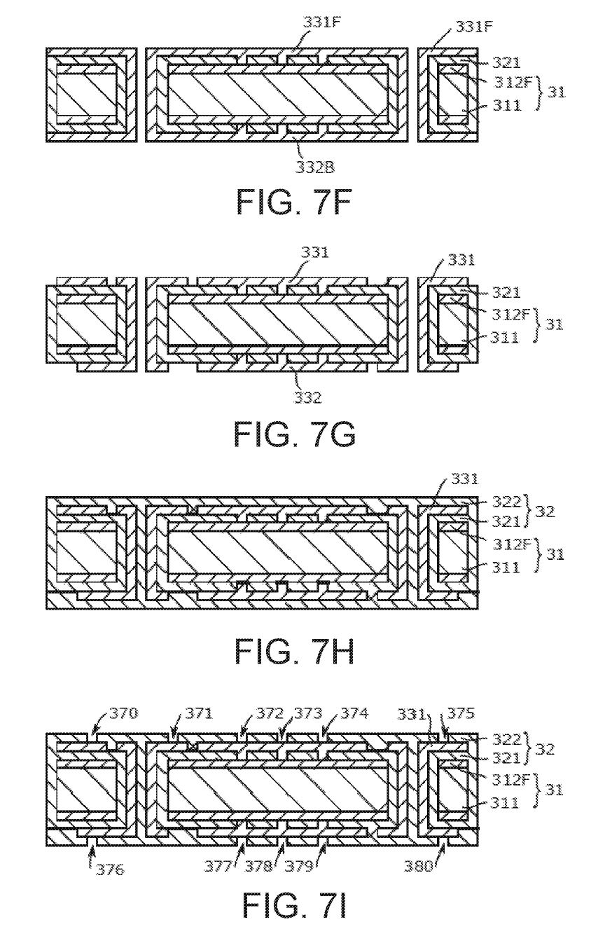

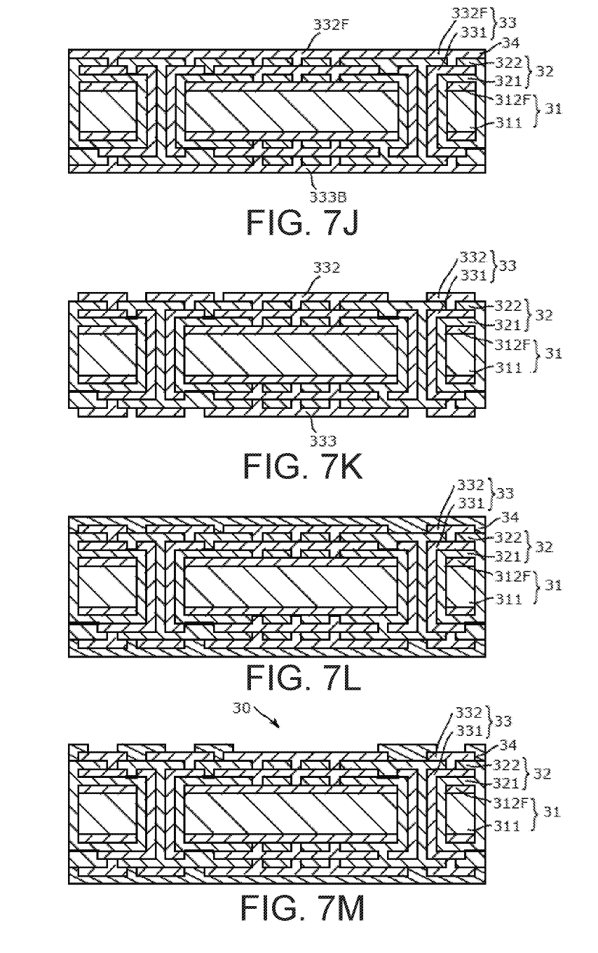

A printed circuit board 30 of Embodiment 3 will be described below with reference to FIGS. 6 and 7A to 7M. FIG. 6 is a cross-sectional view schematically showing a printed circuit board 30 of Embodiment 3. FIGS. 7A to 7M are cross-sectional views of one example of the manufacturing process of the printed circuit board 30 of Embodiment 3. In each drawing, the X-axis, Y-axis, and Z-axis are the same as in Embodiments 1 and 2.

### <Configuration of Printed Circuit Board 30>

As shown in FIG. 6, similar to the printed circuit board 10 of Embodiment 1, the printed circuit board 30 includes a metal core substrate 31, insulating layer 32, wiring pattern 33, and solder resist layer 34. However, in the metal core substrate 31, a second metal layer 312 is formed on both surfaces of a first metal layer 311. Furthermore, in a similar manner to Embodiment 2, the insulating layer 32, wiring pattern 33, and solder resist layer 34 are formed on both surfaces of the metal core substrate 31.

As described above, the metal core layer 31 has the second metal layer 312 laminated on both surfaces of the first metal layer 311.

As described in relation to FIG. 2, in order to improve strength beyond that of a substrate with the same thickness made of only the second metal layer, it is preferable that the thickness of the second metal layer be less than the thickness of the first metal layer. In the present embodiment, the second metal layer 312 is laminated on both surfaces of the first metal layer 311; thus, to be exact, it is preferable that the sum of the thickness of the second metal layer 312 be less than the thickness of the first metal layer 311. If the thickness of the metal core substrate 31 is 120 μm, for example, then it is preferable that the thickness of the first metal layer 311 be greater than 60 μm, and that the thickness of the respective layers forming the second metal layer 312 be less than 30 μm.

Further, the second metal layer being formed on both surfaces of the first metal layer 311 suppresses warping caused by differences in thermal expansion coefficients more than if the second metal layer were formed on only one surface. In addition, a Cu wiring layer is connected by a via to the second metal layer, which is Cu, and thus adhesiveness is good and there is an improvement in electrical characteristics.

### <Manufacturing Process of Printed Circuit Board 30>

The manufacturing process of the printed circuit board 30 will be described below with reference to FIGS. 7A to 7M. The general flow of the fabrication of the metal core substrate 31, the forming of the insulating layer 32 and wiring pattern 33, and the forming of the solder resist layer 34 is similar to Embodiments 1 and 2. However, as described above, in the printed circuit board 30 of Embodiment 3, the second metal layer 312 is formed on both surfaces of the first metal layer 311; thus, Embodiment 3 includes steps that differ from the manufacturing processes of Embodiments 1 and 2.

A more specific description will be provided below.

First, the metal core substrate 31 is formed. Specifically, as shown in FIG. 7A, the first metal layer 311 is prepared, and then as shown in FIG. 7B, second metal layers 312F and 313B are laminated on both surfaces of the first metal layer 311. The lamination of the second metal layers 312F and 313B is performed by plating, for example. As shown in FIG. 7C, holes 341 to 344 are formed in the metal core substrate 31 by mechanical processing or by an etching treatment, for example.

Next, the insulating layer 32 and wiring pattern 33 are formed.

First, the first insulating layer 321 is formed so as to fill the holes 341 to 344 and cover the metal core substrate 31, and the portions corresponding to the holes 341 to 344 are hole processed (opened). Accordingly, as shown in FIG. 7D, the first insulating layer is provided on the side walls of the through-holes, in which openings are provided.

Next, as shown in FIG. 7E, holes 351 to 356 are formed in the first insulating layer 321 corresponding to the front and rear of the substrate. Thereafter, as shown in FIG. 7F, first metal covering layers 331F and 332B that have been Cu plating processed are formed so as to fill in the holes 351 to 356 and to be disposed on the front and rear.

Next, as shown in FIG. 7G, the first metal covering layers 331F and 332B are etched to form first wiring layers 331 and 332. A portion of the first wiring layer 331 on the front side and a portion of the first wiring layer 332 on the rear side are electrically connected to the second metal layers 312F and 313B, respectively, via the holes 351 to 356 and grounded to the ground plane.

Moreover, as shown in FIG. 7H, the second insulating layer 322 is formed on the front and rear of the substrate so as to cover the surface of the first wiring layers 331 and 332, and as shown in FIG. 7I, holes 370 to 380 are formed in the second insulating layer 322.

As shown in FIG. 7J, second metal covering layers 332F and 333B that cover the front and rear of the substrate while filling in the holes 370 to 380 are formed on the front and rear of the substrate, and as shown in FIG. 7K, the second metal covering layers 332F and 333B are etched to form the second wiring layers 332 and 333.

Finally, as shown in FIG. 7L, the solder resist layer 34 is formed on the front and rear of the substrate so as to cover the second wiring layers 332 and 333, and as shown in FIG. 7M, the solder resist layer 34 is patterned (developed) to expose the second wiring layers 332 and 333.

Electrodes for electronic circuit component mounting are exposed on the front side via openings in the solder resist. Furthermore, external electrodes for solder bores are exposed on the rear side as necessary.

Thereafter, the printed circuit board is divided into individual boards, and camera components are attached thereto, in a similar manner to Embodiments 1 and 2.

As described above, in Embodiment 3, it is possible to obtain a metal core substrate that is stronger than a substrate made of only the second metal material, in a similar manner to Embodiment 1. Furthermore, it is possible to obtain a metal core substrate with a higher electrical conductivity than a substrate made of only the first metal material. Moreover, it is possible to obtain a metal core substrate with a higher thermal conductivity than a substrate made of only the first metal material.

In addition, the second metal layer 312 (312F and 313B) is formed on both surfaces of the first metal layer 311, and the wiring pattern 33 is formed on both surfaces of the metal core substrate 31; thus, it is possible to further reduce the size and power consumption of the printed circuit board 20. Furthermore, the second metal material is provided on both sides of the substrate, which can also inhibit warping.

### Embodiment 4

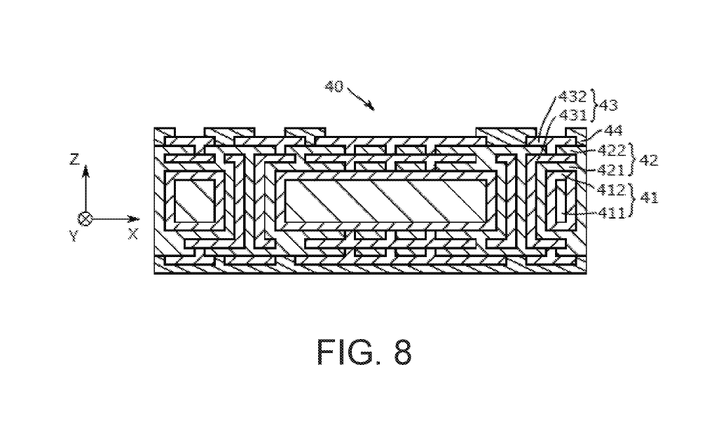

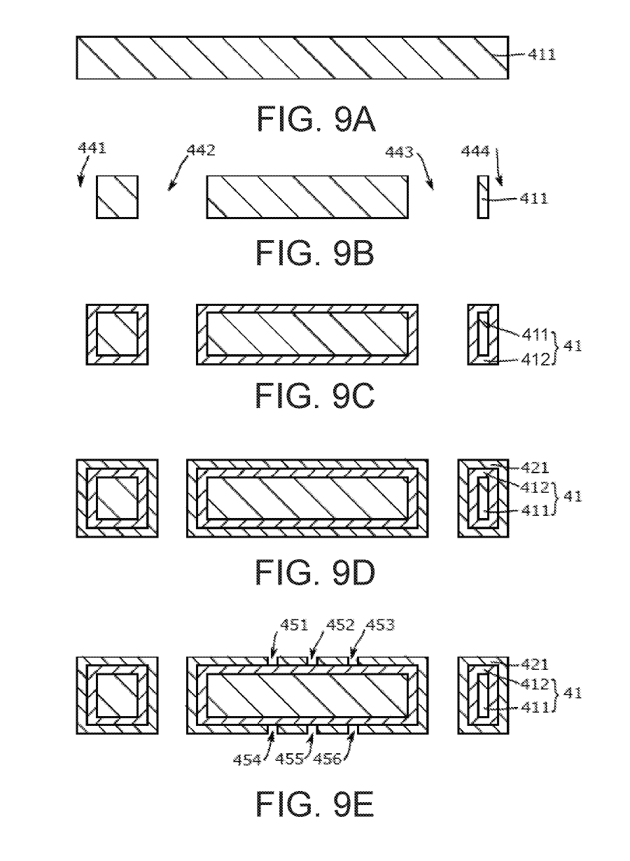

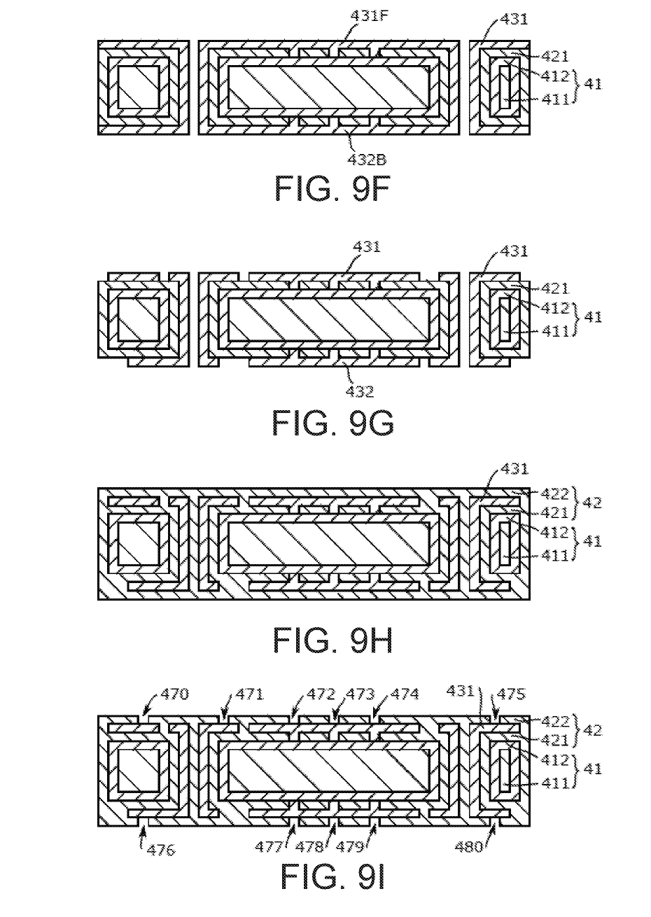

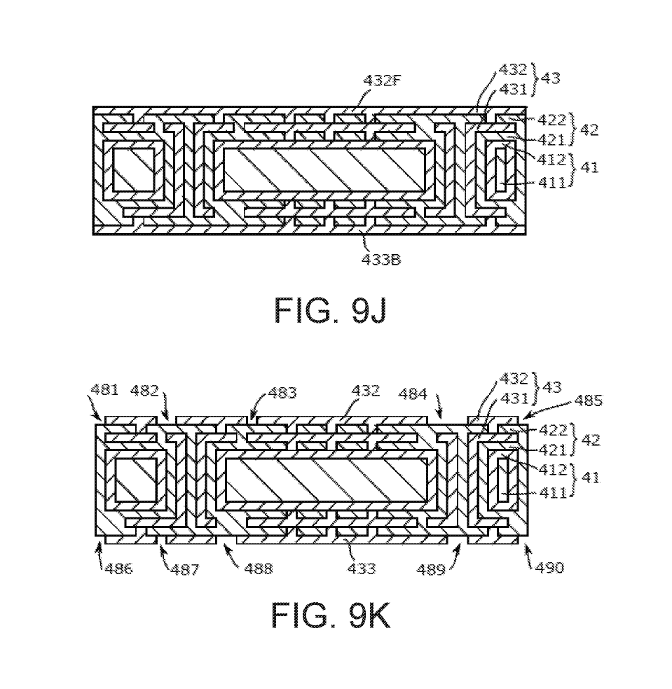

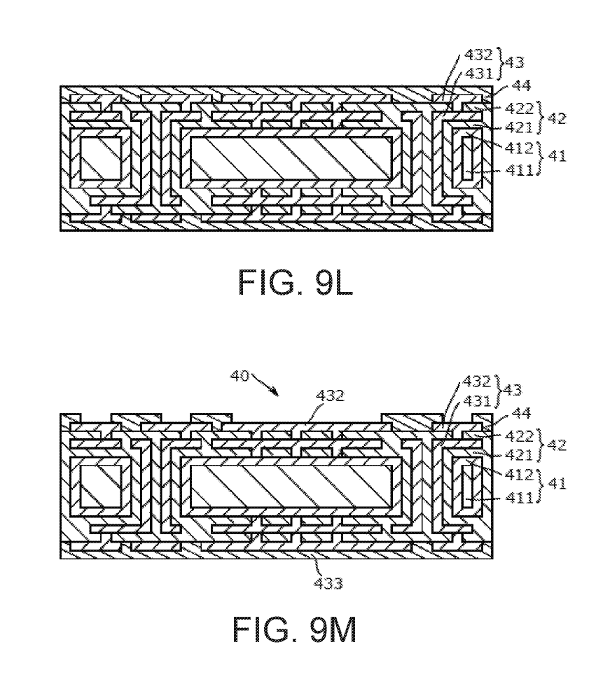

A printed circuit board 40 of Embodiment 4 will be described below with reference to FIGS. 8 and 9A to 9M. FIG. 8 is a cross-sectional view schematically showing a printed circuit board 40 of Embodiment 4. FIGS. 9A to 9M are cross-sectional views of one example of the manufacturing process of the printed circuit board 40 of Embodiment 4. In each drawing, the X-axis, Y-axis, and Z-axis are the same as in Embodiments 1 to 3.

### <Configuration of Printed Circuit Board 40>

As shown in FIG. 8, similar to the printed circuit board 10 of Embodiment 1, the printed circuit board 40 includes at least a metal core substrate 41, insulating layer 42, wiring pattern 43, and solder resist layer 44. However, in the metal core substrate 41, a second metal layer 412 is formed on both surfaces of a first metal layer 411, in a similar manner to Embodiment 3. Furthermore, in a similar manner to Embodiments 2 and 3, the insulating layer 42, wiring pattern 43, and solder resist layer 44 are formed on both surfaces of the metal core substrate 41.

In the metal core substrate 41 of Embodiment 4, the second metal layer 412 laminated on both surfaces of the first metal layer 411 is formed to surround the first metal layer 411, including the through-hole portions.

With such a configuration, the current flowing between the upper side (positive side in the Z-axis direction) and the lower side (negative side in the Z-axis direction) of the printed circuit board 40, for example, flows through the second metal layer 412, which has a high conductivity, thus making it possible to suppress the generation of heat. Furthermore, the grounded GND wiring is also present on the inner walls of the through-holes, and thus it is possible to stably bring the GND potential of the rear surface to the front side. Moreover, the heat that is generated is emitted to outside via the second metal layer 412, which has high thermal conductivity, and thus the configuration has excellent heat dissipating characteristics. This point could also be said for Embodiments 1 to 3.

### <Manufacturing Process of Printed Circuit Board 40>

The manufacturing process of the printed circuit board 40 will be described below with reference to FIGS. 9A to 9M. The general flow of the fabrication of the metal core substrate 41, the forming of the insulating layer 42 and wiring pattern 43, and the forming of the solder resist layer 44 is similar to Embodiments 1 to 3. However, as described above, in the printed circuit board 40 of Embodiment 4, the second metal layer 412 is formed on both surfaces of the first metal layer 411, in a similar manner to Embodiment 3, and further formed on side walls of holes 441 to 444. Therefore, there are steps in Embodiment 4 that differ from the manufacturing processes of Embodiments 1 and 2. Moreover, in the printed circuit board 40 of Embodiment 4,the second metal layer 412 is formed so as to surround both surfaces of the first metal layer 411, and thus the manufacturing process differs from that of the manufacturing process in Embodiment 3.

A more specific description will be provided below.

First, as shown in FIG. 9A, the first metal layer 411 is prepared. Next, as shown in FIG. 9B, mechanical processing such as with a drill or an etching treatment, for example, is used to form holes 441 to 444 in the first metal layer 411.

Then, as shown in FIG. 9C, plating, for example, is used to form the second metal layer 412 so as to surround the first metal layer 411 and the through-holes. By looking at the through-holes 442 and 443 in the drawings it can be seen that the layer is formed on the inner walls thereof. The metal core substrate 41 is fabricated by the above.

Next, the insulating layer 42 and wiring pattern 43 are formed.

First, as shown in FIG. 9D, a first insulating layer 421 is formed on the front and rear of the metal core substrate 41. If the holes 441 to 444 were filled by the first insulating layer, the holes are re-opened, with the first insulating layer remaining on the side walls.

Next, as shown in FIG. 9E, holes 451 to 456 are formed in the first insulating layer 421 on the front side and rear side. Next, as shown in FIG. 9F, first metal covering layers 431F and 432B are formed to fill the holes 451 to 456 and to cover the front side and rear side. The through-holes 441 to 444 may be completely filled or may be remained so as to form through-holes

Next, as shown in FIG. 9G, the first metal covering layer is patterned to form a first wiring layer 431 on the front side and a first wiring layer 432 on the rear side.

Then, as shown in FIG. 9H, the front and the rear of the substrate are covered, and if the through-holes have empty portions, the second insulating layer 422 is formed so as to fill in the empty portions and to cover the first wiring layers 431 and 432. Thereafter, as shown in FIG. 9I, holes 470 to 480 are formed in the second insulating layer 422 on the front and rear. Next, as shown in FIG. 9J, second conductive covering layers 432F and 433B are formed filling in the holes 470 to 480 and covering the rear and front sides of the substrate. Then, as shown in FIG. 9K, the second conductive covering layers 432F and 433B are patterned by etching to form the second wiring layers 432 and 433.

Thereafter, as shown in FIG. 9L, the solder resist layer 44 is formed on the front and rear sides of the substrate, and as shown in FIG. 9M, the solder resist layer 44 is partially removed by developing (etching) to expose the second wiring layers 432 and 433.

The mounting electrodes for the electronic circuit components are exposed at the second wiring layer 432, and if an external connection electrode is necessary, the external connection electrode is exposed at the second wiring layer 433.

Thereafter, the printed circuit board is divided into individual boards, and camera components are attached thereto, in a similar manner to Embodiments 1 to 3. In all embodiments, the components to be mounted include, but are not limited to, active elements such as semiconductor devices, passive components such as chip resistors or chip capacitors, and the like.

As described above, in Embodiment 4, it is possible to obtain a metal core substrate that is stronger than a substrate made of only the second metal material, in a similar manner to Embodiment 1. Furthermore, it is possible to obtain a metal core substrate with a higher electrical conductivity than a substrate made of only the first metal material. Moreover, it is possible to obtain a metal core substrate with a higher thermal conductivity than a substrate made of only the first metal material.

In addition, in a similar manner to Embodiment 3, the second metal layer 412 is formed on both surfaces of the first metal layer 411, and the wiring pattern 43 is formed on both surfaces of the metal core substrate 41; thus, it is possible to further reduce the size and power consumption of the printed circuit board 40, and also possible to inhibit warping.

Moreover, the high conductivity second metal layer 412 forms a current path across both sides in the thickness direction (Z-axis direction) of the metal core substrate 40, which makes it possible to inhibit heat generated by conduction. Furthermore, the high thermal conductivity of the second metal layer 412 makes it possible to obtain a printed circuit board with excellent heat dissipating characteristics.

### Other Embodiments

Below is an explanation of the improvement in rigidity of the printed substrate. The meaning of rigidity is explained as “a characteristic resistance to deformation when a force is exerted on and attempts to deform an object.” Expressed in a different way, “rigidity” means the degree of difficulty in changing (deforming) the dimensions of an object with a bending or twisting force, and in this aspect, “high rigidity” means an excellent ability to keep a flat substrate flat.

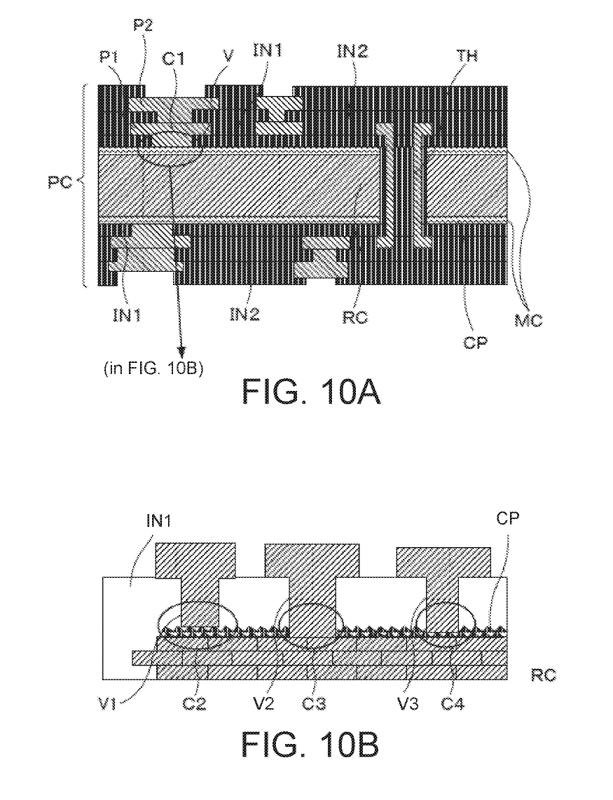

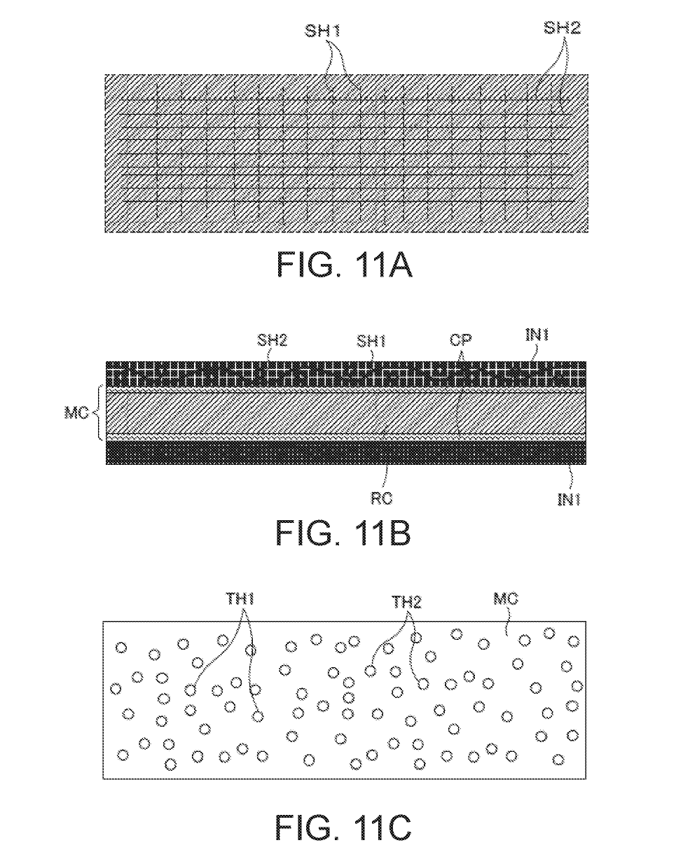

The present explanation will continue with reference to FIGS. 10A to 11C. FIGS. 10A and 10B are views explaining the adhesiveness between a copper plating film CP and an insulating layer IN1. FIGS. 11A to 11C is a view explaining the rigidity of a printed circuit board PC shown in FIG. 10A to which a reinforcing layer has been added. The present embodiment uses the structure of Embodiment 3, i.e., the structure shown in FIG. 6 described above, but is applicable to all embodiments (Embodiment 1 to Embodiment 4). In other words, the explanation will involve the characteristics of the plating layers 112, 212, 312, and 412 in each embodiment, the adhesiveness with the insulating layers 121, 221, 321, and 421, and furthermore, the relationship with a reinforcing layer such as a sheet woven with glass fibers.

Rigidity describes the ability of the metal core substrate MC, or the printed circuit board PC having the metal core substrate MC, to maintain flatness. In other words, it is the ability to maintain flatness while also having a certain degree of hardness against external forces, stress, heat, and other various forces. For example, in a bifocal camera module or the like, the use of a substrate having this flatness is advantageous in making it simple to optically adjust both imaging elements. In order to fabricate camera modules that are both thin and small, it is very important for the printed circuit board PC to be thin, rigid, and strong against destruction. The camera may also be trifocal or another multifocal camera.

Next, there are three main types of materials for a printed circuit board: a resin substrate, a ceramic substrate such as glass or alumina, and a metal substrate made of copper, aluminum, or SUS. A resin substrate, however, is mechanically weak, sensitive to temperature, and susceptible to deformation. Furthermore, a ceramic substrate, while having flatness and hardness, increases in fragility the thinner the substrate becomes, and will immediately break if impacted. Moreover, the metal substrate is problematic in having large thermal expansion and warping.

Thus, to overcome these defects, there is demand for a printed circuit board that can maintain rigidity. In large-sized printed circuit boards using the present structure, warping is inhibited, which can improve workability during manufacturing. The present embodiment achieves such rigidity by using a metal core substrate made by applying copper plating to both sides of an SUS core substrate RC. This will be explained below. An intermediary layer may be disposed between the copper plating film CP and the core substrate RC.

First, as shown in FIG. 10B, the copper plating film CP will be explained. In FIG. 10B, the reference character of the SUS layer is shown as RC, and the copper plating layer is shown as CP (copper plating). The copper plating film CP is Cu plating used in the printed circuit board PC and is immersed in a plating solution and formed electrolessly and/or by an electric field. The crystalline structure is small and is a polycrystalline structure, with growth in the thickness direction, and thus exhibits a columnar organization; therefore, when the printed circuit board PC bends, there is a tendency for cracks to be susceptible to occurring along the grain boundaries of the columnar crystal structure, resulting in a relatively early break. Furthermore, when considering the adhesiveness of resin, the polycrystalline structure is grown along the thickness direction and thus the surface has a fine roughness, which causes higher adhesiveness compared to a regular metal. Moreover, the copper plating layer CP is a polycrystalline structure, and thus it is possible to make the degree of roughness more conspicuous via etching. This is because, normally, when considering the etching rate of grains and grain boundaries, the etching rate of the grain boundaries is higher.

The present invention focuses on the configuration below in order to employ favorable features. Namely, a hard SUS substrate, for example, is used as the main metal core substrate MC, and a copper plating layer CP is formed on both sides of the metal core substrate MC. This structure has the following advantages described below. The plating layer CP could be copper, silver, platinum, gold, Ni, Cr, or the like, but copper is used in this example.

First, the advantages of an increase in adhesiveness between the copper plating layer CP and insulating layer IN1 will be described below. The copper plating layer CP is polycrystalline, and thus the surface has fine recesses and protrusions. Further, if etched, the boundaries around the grains will be removed, which will make the recesses and protrusions more conspicuous. There could also be a CZ treatment or the like. In other words, the surface becomes rough. The recesses and protrusions bring out an anchor effect, which confers excellent adhesiveness with the resin of the insulating layer IN1. FIG. 10B schematically shows these characteristics. The portion indicated by the triangles is the polycrystalline plating layer. As described above, many polycrystalline layers are laminated, and the surface polycrystalline layer is etched to develop recesses and protrusions.

Second, the advantages of using a filler to further increase rigidity will be described below. The filler is in a granular shape, crushed shape, short fiber shape (needle shape), woven fiber sheet shape, or the like. In any case, the filler is harder than the resin, and thus increases rigidity when mixed into the resin. Examples of the granular shape, crushed shape, and short fiber shape filler include a silicon oxide film, aluminum oxide, needle-shaped glass fiber, and needle-shaped carbon or graphite fiber. Compared to the fibers of a sheet, these are each shorter in length and have a smaller diameter, and each moves independently; thus, even if hardened with the resin, the planar strength and flatness are lower than the fiber sheet described below.

Meanwhile, a sheet SH is a reinforcing sheet woven with reinforcing fibers such as carbon fibers or glass fibers. This is schematically shown in FIG. 11A. The characteristic of the sheet is that it is thinly woven in two dimensions (in a planar shape), or namely, is woven like a cloth. As one example of the sheet SH, a large number of vertical threads SH1 and horizontal threads SH2 are arranged next to each other and woven with a needle. Imagine, for example, a handkerchief. A single handkerchief by itself is soft and can warp and deform in the vertical or horizontal directions, but when woven together with an adhesive agent or the like is lightly applied thereto to harden it, the rigidity of the handkerchief increases, and it becomes harder for the handkerchief to be separated. Moreover, the fibers are woven like a cloth, and thus it is also possible to prevent vertical and horizontal deformations and warping of the cloth. This would be further improved if the material were glass or carbon. In addition, as shown in FIG. 11B, a sheet-shaped insulating layer IN1 is bonded to both surfaces of the metal core substrate MC. The resin of the insulating layer IN1 adheres to the recesses and protrusions of the copper plating layer CP and is integrated with the substrate by sheet-shaped reinforcing fibers (a reinforcing filler) being attached to the entire surface of the metal core substrate MC. In other words, the insulating layer IN1, in which the reinforcing sheet SH is inserted and which has been hardened with the resin, maintains a planar shape while being adhered to the copper plating layer CP by the anchor effect; thus, this further increases the rigidity and flatness of the printed circuit board PC.

Third, the advantage of contact with the metal core substrate through a via will be described below. FIG. 10A shows the structure of the printed circuit board PC, and the structure in the portion in C1 indicated by the circle is for schematically describing three types in FIG. 10B. The plating film CP has a polycrystalline structure and has columnar structures in the thickness direction. These structures are schematically shown as triangles in FIG. 10B. In practice, fine crystals of various sizes would be randomly arranged next to each other in the vertical and horizontal directions and laminated in this state, and the structure would appear as if a plurality of layers had been laminated together. The copper plating film CP having these fine crystals has the surface thereof made rough by the process described below, and an oxide film is then formed on the surface.

The manufacturing process will be reviewed a little below. With respect to the metal core substrate MC, first the SUS substrate (RC) is prepared and then a plating process is performed to form the copper plating film CP on both surfaces. Furthermore, for adhesiveness with the insulating layer, the copper plating film undergoes a surface roughening treatment by a CZ process or an etching process. Then, as shown in FIG. 11C, through-holes TH1 and dummy holes TH2 are formed dispersed uniformly to a certain degree by etching. After the through-holes are formed, the copper plating film may be formed, including in the holes. Next, at least one layer of a conductive pattern P that has undergone an insulating process by the insulating layer IN is formed on each of the front and rear of the metal core substrate MC. A contact hole (via) V is formed in the first insulating layer IN1, and the copper plating film CP is exposed at the bottom, for example. The electrode P1 is formed by plating in this hole. In such a process, the insulating layer undergoes a hardening treatment, and hole processing via etching or a laser is performed in order to form holes, and the holes are filled with an etchant. When of the above steps are completed, the copper plating film CP has an oxide film formed thereon, and ions, water, or the like are trapped in the grain boundaries. Due to this, if the plating process for the electrode P1 were performed as-is, there would be fluctuations in resistance and an effect on characteristics due to an increase in resistance, ion migration, and the like.

FIG. 10B shows a solution in order to solve this problem. The contact C2 is a structure having this problem, and the figure shows that processing of the contact hole V1 has not been performed at all. The contact C3 is the first solution to the problem, in which the copper plating film CP is removed via the contact hole V2 to expose the SUS layer. Due to this, a large crystalline structure that does not have an oxide film and that extends flat in the planar direction is exposed at the bottom of the contact hole; thus, it is difficult for ions, water, or the like to become trapped here, which makes it possible to have favorable contact characteristics. It is important to over-etch in order to completely expose the rolled Cu layer. Due to SUS having high resistance, a copper plating film, Ag plating, or the like may be applied again via an intermediary layer. In regard to the contact C4, the surface layer of the copper plating film CP is removed via the contact hole V3 to expose the planarized copper plating film. Due to this, the oxide film is removed and a plating layer that has become a certain degree of flatness as compared to the previously rough surface is exposed at the bottom of the contact hole; thus, it is difficult for ions, water, or the like to become trapped here, which makes it possible to have favorable contact characteristics. In this manner, in all embodiments, a copper plating film is used for the surface of the core layer, and an insulating layer containing a sheet woven with glass fibers, for example, is adhered to the copper plating film, which results in a further increase in rigidity.

Although it is possible to state “in all embodiments” as above, it is also possible to use, as the metal core substrate MC, a metal plate whose primary material is copper that is harder than the copper plating layer CP. For example, it is possible to use a material, such as Cu—Fe, Cu—Cr, Cu—Ni—Si, Cu—Ti, Cu—Be—Co, or the like, as a metal core substrate MC in which copper is contained as the primary material and impurities are mixed to make the material harder than substantially pure copper.

### SUMMARY

As described above, the printed circuit board 10 (20, 30, 40) includes a metal core substrate 11 (21, 31, 41), an insulating layer 12 (22, 32, 42) formed on a surface of the metal core substrate 11 (21, 31, 41), and a wiring pattern 13 (23, 33, 43) formed on the insulating layer 12 (22, 32, 42). The metal core substrate 11 (21, 31, 41) includes a first metal layer 111 (211, 311, 411) that contains a first metal material such as stainless steel, for example, and a second metal layer 112 (212, 312, 412) that contains a second metal material such as copper, for example, and that is laminated on the first metal layer 111 (211, 311, 411). The elastic modulus of the second metal layer 112 (212, 312, 412) is lower than the elastic modulus of the first metal layer 111 (211, 311, 411), and the thermal conductivity of the second metal layer 112 (212, 312, 412) is higher than the thermal conductivity of the first metal layer 111 (211, 311, 411).

This embodiment makes it possible to obtain a metal core substrate that is enhanced in strength than a substrate made of only the second metal material; thus, it is possible to obtain a printed circuit board that is thin yet strong. Furthermore, it is possible to obtain a metal core substrate that has a higher thermal conductivity than a substrate made of only the first metal material; thus, it is possible to obtain a printed circuit board that has excellent heat dissipating characteristics.

Moreover, the electrical conductivity of the second metal layer 112 (212, 312, 412) is higher than the electrical conductivity of the first metal layer 111 (211, 311, 411), which makes it possible to obtain a metal core substrate that has a higher electrical conductivity than a substrate made of only the first metal material. Accordingly, it is possible to inhibit heat generated by conduction more than in a substrate made of only the first metal material.

In addition, the second metal layer 112 (212) is laminated on a surface on one side of the first metal layer 111 (211), which makes it possible to obtain an even thinner printed circuit board.

In such a case, the thickness of the second metal layer 112 (212) is less than the thickness of the first metal layer 111 (211), thereby making it possible to obtain a thin printed circuit board while maintaining a certain degree of strength.

Alternatively, the second metal layer 312 (412) is laminated on both surfaces the first metal layer 311 (411), thereby making it possible to use both surfaces of the metal core substrate, which allows the printed circuit board to be reduced in size.

In such a case, the thicknesses of the second metal layer 312 (412) laminated on both surfaces of the first metal layer 311 (411) are substantially the same, which inhibits warping of the printed circuit board in either thickness direction.

The total thickness of the second metal layer 312 (412) laminated on both surfaces of the first metal layer 311 (411) is less than the thickness of the first metal layer 311 (411), which makes it possible to obtain a thin printed circuit board while maintaining a certain degree of strength.

The second metal layer 412 laminated on both surfaces of the first metal layer 411 is connected so as to surround the first metal layer 411, thereby causing the second metal layer, which has a high electrical conductivity, to form a current path across both sides of the metal core substrate in the thickness direction (Z-axis direction). This can inhibit heat generated by conduction. This leads to a reduction in power consumption when the printed circuit board is used as a camera module component, for example.

Furthermore, the metal core substrate 11 (21, 31, 41) may have a third metal layer 113 (see FIG. 12) between the first metal layer 111 (211, 311, 411) and second metal layer 112 (212, 312, 412). This embodiment increases the adhesion between the first metal layer 111 (211, 311, 411) and second metal layer 112 (212, 312, 412).

Moreover, the insulating layer 12 (22, 32, 42) contains a resin containing glass fibers, thus further increasing the strength of the printed circuit board.

The camera module may be formed including the printed circuit board 10 (20, 30, 40) described above and an imaging element mounted on the printed circuit board 10 (20, 30, 40). This embodiment makes it possible to provide a thinner camera module while maintaining a necessary degree of strength.

Embodiments of the present invention were described above, but the present invention is not limited thereto. The material, shape, and arrangement of the respective members described above are not limited to the embodiments, and various modifications can be made without departing from the spirit of the invention.

When applied to a camera module, electronic circuit components such as the following can be mounted on the printed circuit board. First, an imaging element is mounted as a semiconductor device. The following types of optical packages are then arranged around the imaging element. Although not shown in the drawings, the optical package includes a lens unit, an autofocus actuator provided around the lens unit, a filter unit provided below the lens unit, and a package containing the lens unit, actuator, and filter unit, the package being fixed in position and disposed on the semiconductor device. A plurality of these camera modules may be arranged to have high resolution. When using the printed circuit board of the present disclosure, the rigidity and flatness of the board surface are high, which makes optical adjustment simple. The board also does not break, unlike ceramic, which improves workability.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A printed circuit board, comprising:
a metal core substrate;
an insulating layer formed on a surface of the metal core substrate; and
a wiring pattern formed on the insulating layer,
wherein the metal core substrate comprises a first metal layer made of a first metal material, and a second metal layer made of a second metal material differing from the first metal material, the second metal layer being laminated on the first metal layer,
wherein an elastic modulus of the second metal layer is lower than an elastic modulus of the first metal layer, and
wherein a thermal conductivity of the second metal layer is higher than a thermal conductivity of the first metal layer.

2. The printed circuit board according to claim 1, wherein an electrical conductivity of the second metal layer is higher than an electrical conductivity of the first metal layer.

3. The printed circuit board according to claim 1, wherein the second metal layer is laminated on a top surface of the first metal layer.

4. The printed circuit board according to claim 3, wherein a thickness of the second metal layer is less than a thickness of the first metal layer.

5. The printed circuit board according to claim 1, wherein the second metal layer is laminated on each of a top surface and a bottom surface of the first metal layer, thereby the second metal layer being provided in a plurality.

6. The printed circuit board according to claim 5, wherein thicknesses of the second metal layers laminated on the top and bottom surfaces, respectively, of the first metal layer are same.

7. The printed circuit board according to claim 5, wherein a total of thicknesses of the second metal layers laminated on the top and bottom surfaces of the first metal layer is less than a thickness of the first metal layer.

8. The printed circuit board according to claim 5, wherein the second metal layers laminated on the top and bottom surfaces of the first metal layer are connected at respective edges thereof to form a united layer that surrounds the first metal layer.

9. The printed circuit board according to claim 1, wherein the metal core substrate includes a third metal layer between the first metal layer and the second metal layer for increasing adhesion between the first metal layer and the second metal layer.

10. The printed circuit board according to claim 1,
wherein the first metal material is stainless steel, and
wherein the second metal material is plated copper.

11. The printed circuit board according to claim 1, wherein the insulating layer is made of a resin containing glass fibers.

12. A printed circuit board, comprising:
a metal core substrate;
an insulating layer formed on a front surface and a rear surface of the metal core substrate; and
a wiring pattern formed on the insulating layer,
wherein the metal core substrate comprises a first metal layer that includes, as a main material, a first metal material that is harder than copper, and a second metal layer made of a second metal material that mainly includes copper, the second metal layer being laminated on both surfaces of the first metal layer.

13. A module comprising: the printed circuit board according to claim 12, and an electronic circuit mounted on the printed circuit board.

14. A camera module comprising: the printed circuit board according to claim 12, and an imaging element mounted on the printed circuit board.
